(19) United States
(12) Patent Application Publication
(10) Pub. No.: US 2017/0229915 A1
(43) Pub. Date: Aug. 10, 2017

(54) POWER FEEDING DEVICE

(71) Applicant: Panasonoc Intellectual Property Management Co., Ltd., Osaka (JP)

(72) Inventors: Masanobu KUBOSHIMA, Kanagawa (JP); Toyohiko TSUJIMOTO, Osaka (JP); Hiroshi KOHARA, Aichi (JP); Toshihiro AKIYAMA, Osaka (JP); Mamoru OZAKI, Osaka (JP)

(21) Appl. No.: 15/329,315

(22) PCT Filed: Sep. 24, 2015
(86) PCT No.: PCT/JP2015/004846

§ 371 Date: Jan. 26, 2017

(30) Foreign Application Priority Data
Sep. 26, 2014 (JP) 2014-197091

(51) Int. Cl. H02J 50/12; H02J 50/90; G01R 15/14; H02J 7/02

(52) U.S. Cl. CPC H02J 50/12; H02J 7/025; H02J 50/90; G01R 15/146

(57) ABSTRACT

A power feeding device includes: a series circuit including a primary coil and a capacitor connected in series with each other; a switching circuit and a control circuit. The power feeding device is configured to supply power from the primary coil to a secondary coil of a power receiving device in a non-contact manner. The switching circuit is configured to alternate a direction of a voltage between both ends of the series circuit. The control circuit is configured to control a frequency by which the switching circuit performs alternating operation for alternating the direction of the voltage. The control circuit is configured to: measure a voltage at a connection point between the primary coil and the capacitor; and determine, based on a phase of the voltage, whether current flowing through the primary coil is in a phase advance state or a phase delay state.

### TECHNICAL FIELD

This invention relates to a power feeding device.

### BACKGROUND ART

There has been conventionally a power feeding device configured to supply electric power to a power receiving device in a non-contact manner (e.g., refer to JP 2011-135760 A (hereinafter, referred to as Document 1)). The power feeding device in Document 1 includes a power transmission control circuit, an excite circuit, a power feeding coil circuit and a phase detection circuit.

The excite circuit is a circuit in which an excite coil and a secondary coil of a transformer are connected in series with each other. The power feeding coil circuit is a circuit in which a power feeding coil and a capacitor are connected in series with each other. The excite coil and the power feeding coil are disposed so as to face each other. The power feeding coil circuit further includes a detection coil formed by a core and a coil wound on the core. AC current flowing through the power feeding coil circuit is detected by this detection coil.

The power transmission control circuit includes a voltage controlled oscillator that functions as an oscillator generating an AC voltage depending on a drive frequency. The phase detection circuit detects a phase difference between the AC current detected by the detection coil and the AC voltage generated by the voltage controlled oscillator, and outputs a voltage signal, depending on the phase difference, to the voltage controlled oscillator. The voltage controlled oscillator sets a drive frequency according to the voltage signal from the phase detection circuit, and generates an AC voltage depending on this drive frequency.

Generally if there is a relative positional deviation between a power feeding device and a power receiving device, a resonant frequency of the power feeding coil circuit is changed, and it causes to increase a deviation between the resonant frequency and the drive frequency of the voltage controlled oscillator. Power feeding performance is therefore reduced. On the other hand, in the case of the power feeding device in the above document, even when the resonant frequency of the power feeding coil circuit is changed, the drive frequency of the voltage controlled oscillator is adjusted to be closer to the changed resonant frequency, which can suppress the reduction in the power feeding performance.

Incidentally, since the power feeding device in Document 1 mentioned above includes the detection coil formed by the core and the coil wound on the core in order to directly measure AC current flowing through the power feeding coil circuit, there is a problem that the size of the power feeding device is increased, depending on the detection coil.

### SUMMARY OF INVENTION

It is an object of the present invention to provide a power feeding device, which can realize miniaturization thereof.

A power feeding device of an aspect according to the present invention includes a series circuit, a switching circuit and a control circuit. The series circuit includes a primary coil and a capacitor connected in series with each other. The switching circuit is configured to alternate a direction of a voltage between both ends of the series circuit. The control circuit is configured to control a frequency by which the switching circuit performs alternating operation for alternating the direction of the voltage. The power feeding device is configured to supply power from the primary coil to a secondary coil of a power receiving device in a non-contact manner. The control circuit is configured to: measure a voltage at a connection point between the primary coil and the capacitor; and determine, based on a phase of the voltage, whether current flowing through the primary coil is in a phase advance state or a phase delay state.

### BRIEF DESCRIPTION OF THE DRAWINGS

The figures depict one or more implementations in accordance with the present disclosure, by way of example only, not by way of limitations. In the figures, like reference numerals refer to the same or similar elements.

FIG. 1A is a schematic circuit diagram illustrating one example of a power feeding device according to an embodiment, and FIG. 1B is a schematic circuit diagram illustrating another example of the power feeding device;

FIG. 2A and FIG. 2B are schematic circuit diagrams for explaining basic operation of the power feeding device;

FIG. 3A and FIG. 3B are timing charts for explaining the basic operation of the power feeding device;

FIG. 4A and FIG. 4B are schematic circuit diagrams illustrating a typical power feeding device;

FIG. 5A and FIG. 5B are timing charts for the typical power feeding device;

FIG. 6 is a timing chart for the power feeding device according to the embodiment;

FIG. 7 is a waveform chart for the power feeding device according to the embodiment;

FIG. 8 is a flow chart for the power feeding device according to the embodiment;

FIG. 9 is a graph illustrating a relation between a drive frequency and a coil voltage in the power feeding device according to the embodiment;

FIG. 10 is another flow chart for the power feeding device according to the embodiment; and

FIG. 11 is yet another flow chart for the power feeding device according to the embodiment.

### DESCRIPTION OF EMBODIMENTS

An embodiment below relates generally to power feeding devices and, more particularly, to a power feeding device configured to supply electric power to a power receiving device in a non-contact manner. A power feeding device according to the present embodiment will be described specifically with reference to figures. The configuration mentioned below is merely one example, and the power feeding device of the present teaching is not limited to the following embodiment. Even other than the embodiment, numerous modifications and variations can be made according to designs and the like without departing from the technical ideas of the present teaching.

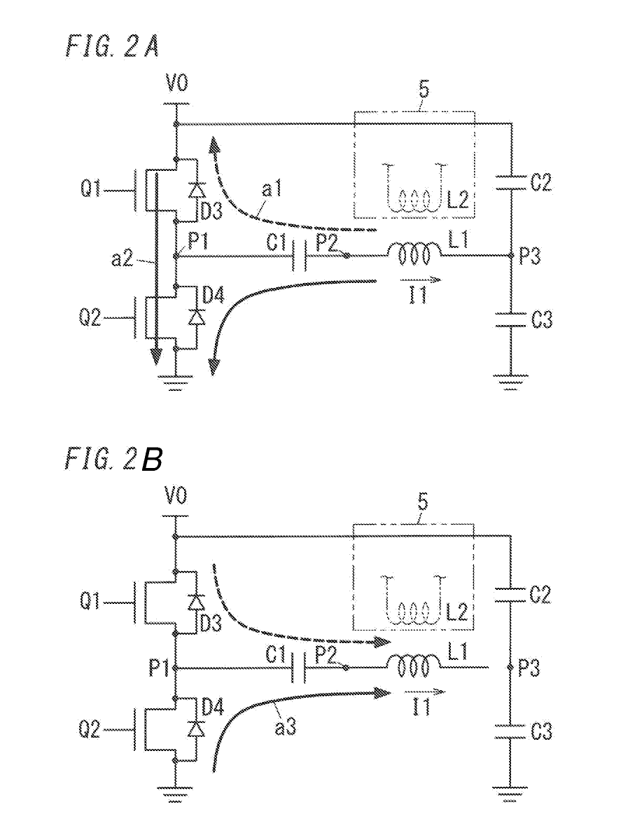

The power feeding device of the present embodiment is, for example, a charging stand that supplies electric power to a power receiving device 5 having therein a battery, such as a charging driver, in a non-contact manner. That is, in the present embodiment, the power receiving device 5 as the charging driver is provided with a secondary coil L2 (refer to FIGS. 2A and 2B), and the power can be supplied from a primary coil L1 described later to the secondary coil L2 in the non-contact manner. The power feeding device is not limited to the charging stand for the charging driver, but may be other apparatus, as long as the power can be supplied to the power receiving device 5 in the non-contact manner.

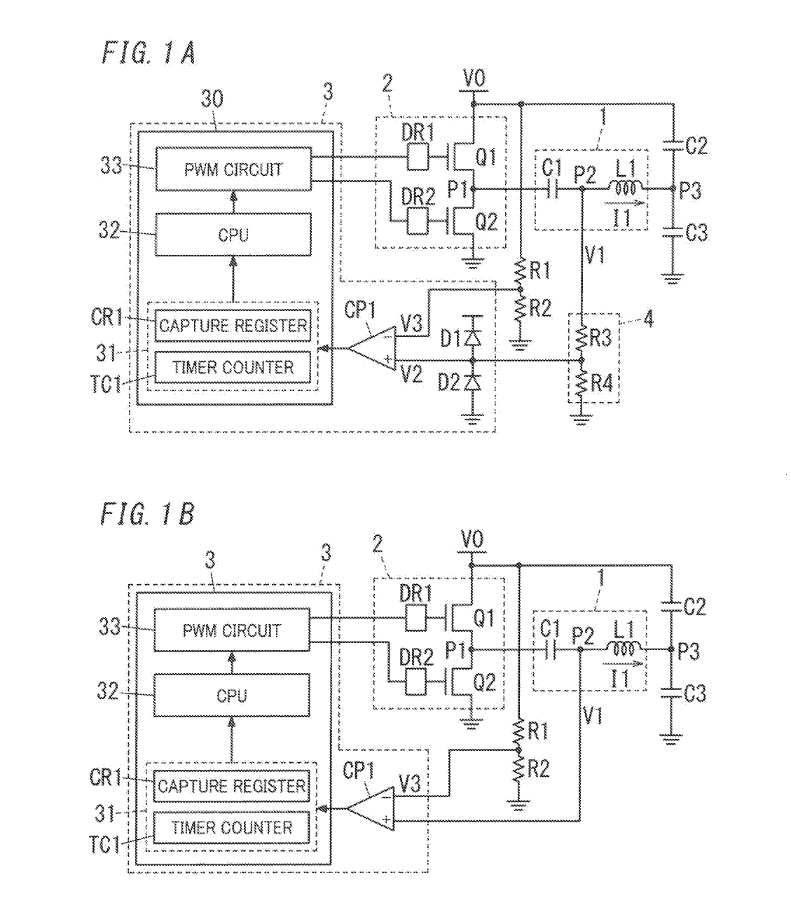

As shown in FIG. 1A, the power feeding device of the present embodiment includes a series circuit 1, a switching circuit 2, a control circuit 3 and a voltage dividing circuit 4.

The series circuit 1 is a circuit that includes a capacitor C1 and a primary coil L1 connected in series with each other. One end of the capacitor C1 (on an opposite side from the primary coil L1) is connected to a midpoint P1 between two switching elements Q1 and Q2 that are connected in series with each other between two terminals of a DC power supply. A power supply voltage V0 of the DC power supply is applied between the two switching elements Q1 and Q2 (refer to FIGS. 1A and 1B). Another end of the capacitor C1 is connected with one end of the primary coil L1. Another end of the primary coil L1 (on an opposite side from the capacitor C1) is connected to a midpoint P3 between two capacitors C2 and C3 that are connected in series with each other between the two terminals of the DC power supply. Furthermore, a connection point P2 between the capacitor C1 and the primary coil L1 is connected to a non-inversion input terminal of a comparator CP1 described later via the voltage dividing circuit 4.

The switching circuit 2 is a so-called half-bridge type switching circuit, and includes: the two switching elements Q1 and Q2 connected in series with each other between the two terminals of the DC power supply; a drive element DR1 for driving the switching element Q1; and a drive element DR2 for driving the switching element Q2. The respective drive elements DR1 and DR2 alternately turn on/off the switching elements Q1 and Q2 according to a PWM signal output from a PWM circuit 33 of an MCU 30 described later, which can alternate a direction of a voltage to be applied to the series circuit 1.

The control circuit 3 includes the MCU 30, the comparator CP1 and diodes D1 and D2, and controls a frequency by which the switching circuit 2 performs alternating operation, namely, a drive frequency for the switching elements Q1 and Q2.

The MCU (Micro Control Unit) 30 includes a timer 31, a CPU (Central Processing Unit) 32 and the PWM (Pulse Width Modulation) circuit 33.

The timer 31 includes a timer counter TC1 and a capture register CR1. The timer counter TC1, when detecting the falling of a voltage signal output from the comparator CP1 (i.e., timing when the voltage signal's level is changed from a high level to a low level), outputs a time counted by the timing, as a count value, to the capture register CR1. The capture register CR1 holds the count value obtained by the timer counter TC1, and outputs it to the CPU 32.

The CPU 32 calculates a phase of a voltage V1 of the primary coil L1 (a voltage at the connection point P2 between the capacitor C1 and the primary coil L1) based on the count value received from the timer 31 (the capture register CR1). The CPU 32 then estimates a phase of current I1 flowing through the primary coil L1 based on the phase of the voltage V1 of the primary coil L1, and determines whether the current I1 is in a phase advance state or a phase delay state. The operation of the CPU 32 will be described later.

The PWM circuit 33 generates a PWM signal based on the voltage signal output from the CPU 32, and outputs the generated PWM signal to the drive elements DR1 and DR2 of the switching circuit 2. The drive elements DR1 and DR2 alternately turn on/off the switching elements Q1 and Q2 by a frequency of the PWM signal output from the PWM circuit 33.

The comparator CP1 includes: a non-inversion input terminal (a first terminal) into which a voltage V2, obtained by the voltage dividing circuit 4 dividing the voltage V1 of the primary coil L1, is input; and an inversion input terminal (a second terminal) into which a reference voltage V3, obtained by resistors R1 and R2 dividing the power supply voltage, is input. The comparator CP1 outputs to the timer 31 a voltage signal depending on whether the voltage V2 is more than, less than or equal to the reference voltage V3.

The non-inversion input terminal of the comparator CP1 is connected with: a diode D2 of which anode is connected to the ground; and a diode D1 of which cathode is connected to the reference voltage V3. The diode D2 has a function of controlling the magnitude of the voltage V2 so that the voltage V2 is not reduced to a value less than the ground. The diode D1 has a function of controlling the magnitude of the voltage V2 so that the voltage V2 is not increased to a value more than the reference voltage V3.

Since the diode D2 is installed in the control circuit 3, the comparator CP1 can be operated by a single power supply. Also since the diode D1 is installed in the control circuit 3, the high-voltage region to be input to the non-inversion input terminal of the comparator CP1 can be cut off, and further the potential of the reference voltage V3 can be increased. In the present embodiment, the diode D2 constitutes a first voltage control circuit, and the diode D1 constitutes a second voltage control circuit.

The voltage dividing circuit 4 includes resistors R3 and R4 connected in series with each other, and divides the voltage V1 of the primary coil L1 so that the voltage V2 to be input to the non-inversion input terminal of the comparator CP1 falls within a range of the input voltage of the comparator CP1. For this reason, as shown in FIG. 1B, the voltage dividing circuit 4 may not need to be provided, in a case where the voltage V1 of the primary coil L1 is within the range of the input voltage of the comparator CP1.

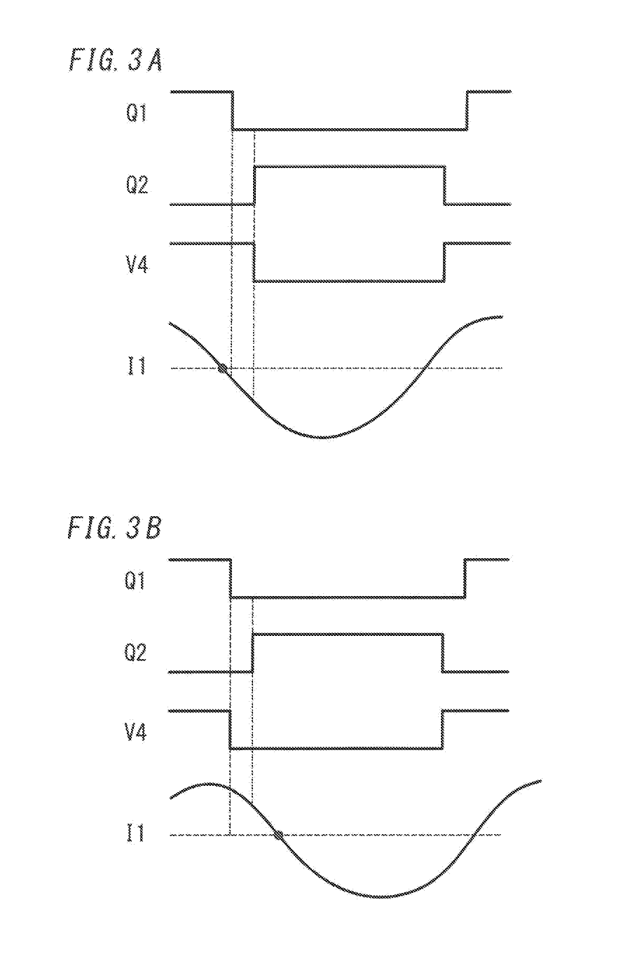

FIG. 2A is a schematic circuit diagram for explaining operation of the switching circuit in a phase advance mode, and FIG. 2B is a schematic circuit diagram for explaining operation of the switching circuit in a phase delay mode. FIG. 3A is a timing chart for the switching circuit in the phase advance mode, and FIG. 3B is a timing chart for the switching circuit in the phase delay mode.

First, the following case will be described, where the switching elements Q1 and Q2 are driven by a drive frequency lower than a frequency at a resonance point of the series circuit 1 (a resonant frequency), namely, where those are operated in the phase advance mode. When the switching element Q1 is turned off from a state where the switching element Q1 is in on and the switching element Q2 is in off, a parasitic diode D3 of the switching element Q1 is turned on, and accordingly, regeneration current flows in a direction denoted by arrow al in FIG. 2A.

When the switching element Q2 is turned on from the above state, through-current flows through the switching elements Q1 and Q2 in a direction denoted by arrow a2 in FIG. 2A, and, in the worst case, the switching elements Q1 and Q2 may be therefore damaged.

Next, the following case will be described, where the switching elements Q1 and Q2 are driven by a drive frequency higher than the resonant frequency, namely, where those are operated in the phase delay mode. When the switching element Q1 is turned off from the state where the switching element Q1 is in on and the switching element Q2 is in off, a parasitic diode D4 of the switching element Q2 is turned on, and accordingly, regeneration current flows in a direction denoted by arrow a3 in FIG. 2B.

When the switching element Q2 is turned on from the above state, zero-voltage switching operation is performed, which is originally desirable. In other words, since the through-current is not generated in the phase delay mode, the switching circuit as mentioned above is desirable to be operated in the phase delay mode. A voltage V4 shown in FIGS. 3A and 3B is a voltage at the midpoint P1 between the two switching elements Q1 and Q2.

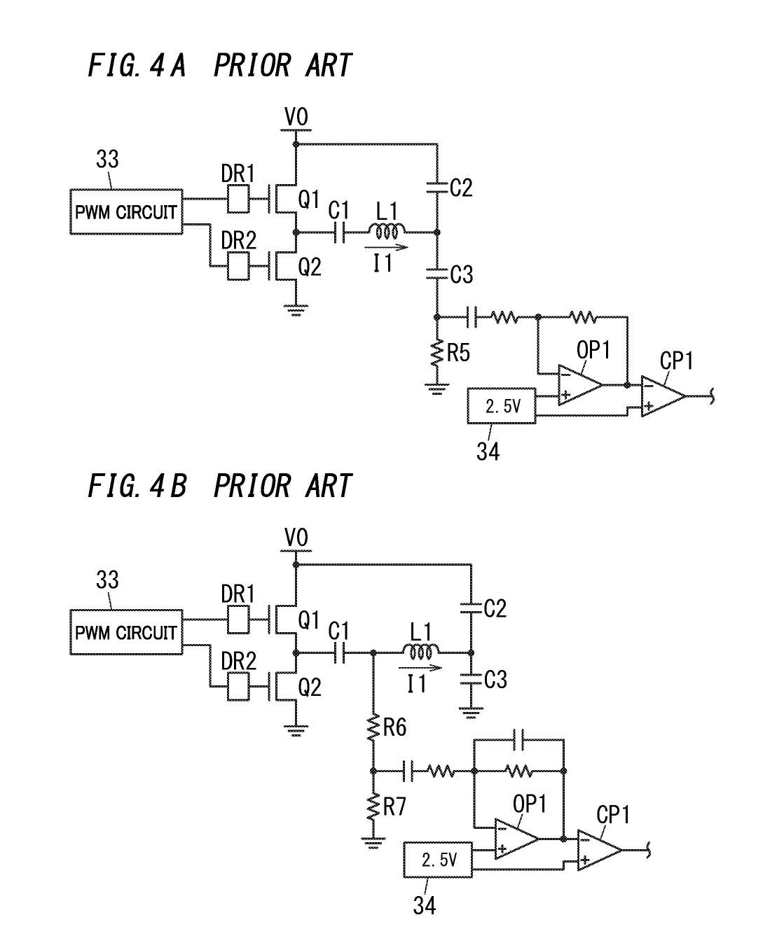

Here a method for determining whether the switching circuit is in the phase advance mode or the phase delay mode is generally to measure the current I1 flowing through the primary coil L1 of the series circuit 1 (a resonance circuit). In this case, a current measuring circuit may include a shunt resistor R5, a 2.5V-power supply 34 and an operational amplifier OP1, as shown in FIG. 4A. Alternatively, a current measuring circuit may include voltage-dividing resistors R6 and R7, a 2.5V-power supply 34 and an operational amplifier OP1, as shown in FIG. 4B. Note that, because those circuits are conventionally well-known, detailed explanations thereof are omitted here.

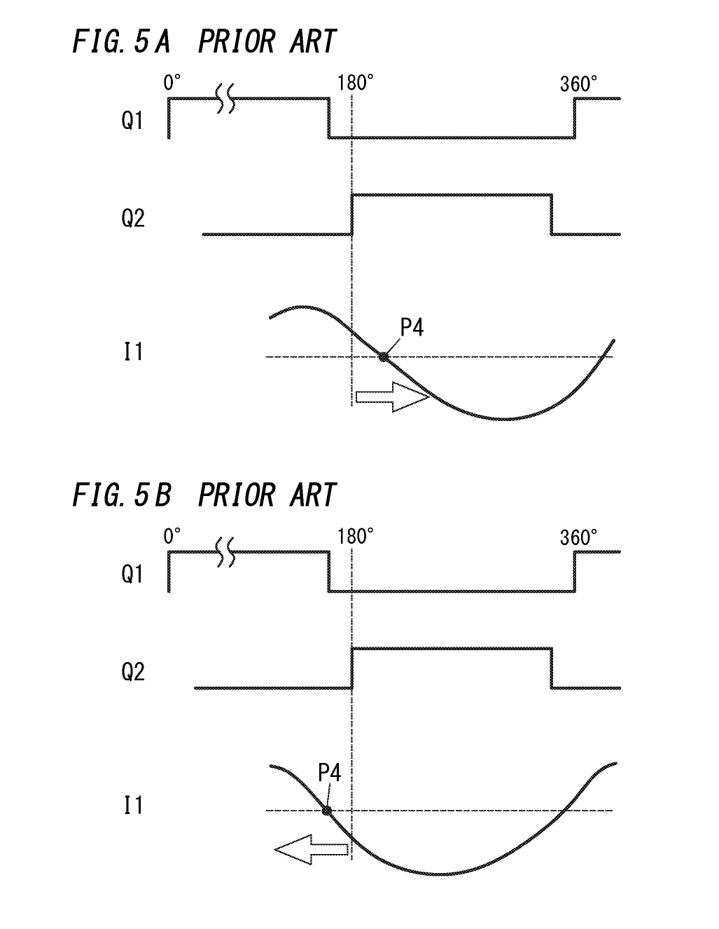

Whether the switching circuit is in the phase advance mode or the phase delay mode can be determined by calculating the phase of the current I1 measured by any one of the above-mentioned current measuring circuits. Specifically, when a phase at a zero-cross point P4 of the current I1 is equal to or more than 180°, as shown in FIG. 5A, it is determined that the switching circuit is in the phase delay mode. On the other hand, when the phase at the zero-cross point P4 of the current I1 is less than 180°, as shown in FIG. 5B, it is determined that the switching circuit is in the phase advance mode.

However, the resistors R5 to R7, the 2.5V-power supply 34, the operational amplifier OP1 and the like are needed in the method for measuring the current I1 flowing through the primary coil L1, as mentioned above. Therefore, there is a problem that the size of the power feeding device is increased, depending on those components.

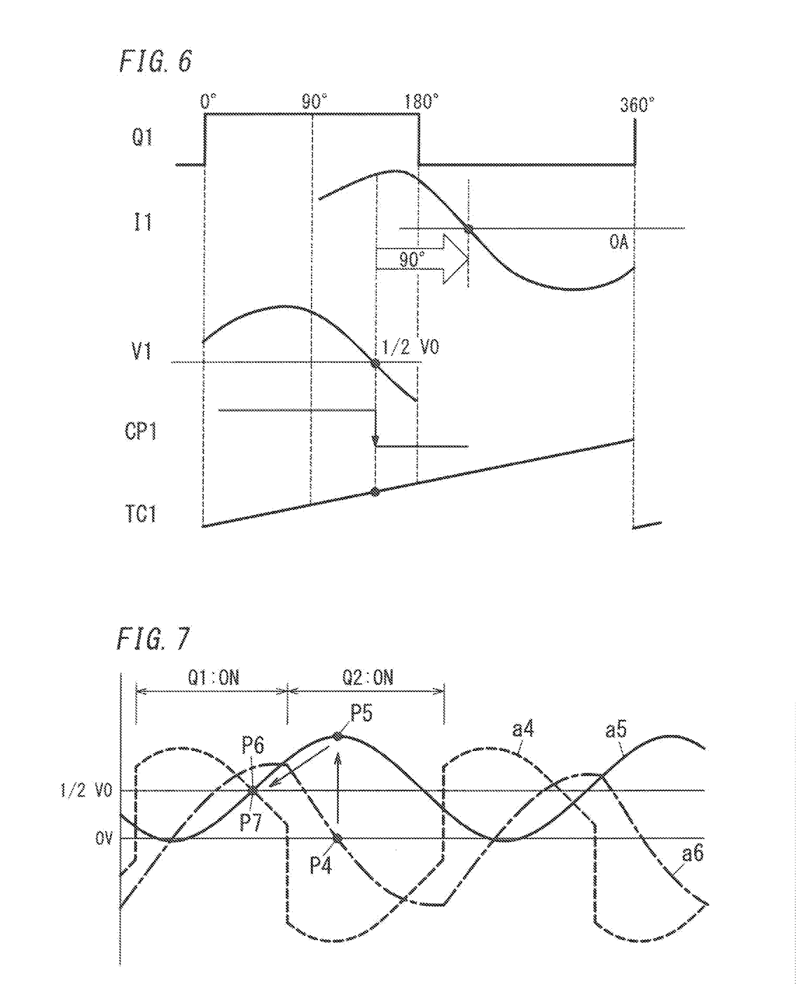

In order to solve this issue, the present embodiment adopts not a method of directly measuring a phase of the current I1 flowing through the primary coil L1, but a method of estimating the phase of the current I1 based on a phase of the voltage V1 of the primary coil L1 which can realize miniaturization of the power feeding device. Hereinafter, the method of estimating the phase of the current will be described in detail with reference to FIGS. 6 to 8.

As shown in FIG. 6, the switching element Q1 on the high-side of the switching circuit 2 is turned on at timing when a phase (the horizontal axis) is 0°, and the timer counter TC1 of the timer 31 starts counting of time at this timing. At this time, the voltage V1 at the connection point P2 between the capacitor C1 and the primary coil L1, namely, the voltage V1 of the primary coil L1 is more than ½×V0, and the comparator CP1 outputs a high-level voltage signal. V0 mentioned here means a power supply voltage of the DC power supply, which is applied between the two switching elements Q1 and Q2, as shown in FIG. 1.

At timing when the voltage V1 of the primary coil L1 becomes ½×V0, the voltage V2 to be input to the non-inversion input terminal of the comparator CP1 becomes equal to the reference voltage V3 to be input to the inversion input terminal thereof, and the comparator CP1 therefore outputs a low-level voltage signal. The timer counter TC1 detects the falling of the voltage signal output from the comparator CP1, and obtains the count value.

The timer counter TC1 then outputs the obtained count value to the capture register CR1. The capture register CR1 holds the count value, and further outputs it to the CPU 32. The CPU 32 calculates a phase of the voltage V1 of the primary coil L1 based on the count value received from the capture register CR1.

When a phase of the current I1 is estimated based on a phase of the voltage V1 of the primary coil L1, it can be regarded that a phase difference of 90° exists between a phase at a point where V1=½×V0 is met and a phase at a zero-cross point of the current I1.

FIG. 7 shows a waveform chart for the power feeding device of the present embodiment, where a broken line a4 denotes the voltage V1, and a solid line a5 denotes the voltage V4 across the capacitor C1 (a voltage at the midpoint P1 between the switching elements Q1 and Q2), and a dashed line a6 denotes the current I1. From this waveform chart, it can be found that the zero-cross point P4 of the current I1 and a maximum point P5 of the voltage V4 are at the same phase. Since the capacitor C1 and the primary coil L1 are connected in series with each other, current flowing through the capacitor C1 is equal to the current I1. Furthermore, a phase difference of 90° exists between a phase of the current flowing through the capacitor C1 and a phase of the voltage V4.

The voltage V4 across the capacitor C1 has an AC waveform with central potential that is equal to or more than 0V. The central potential corresponds to potential at a point P6, and a phase difference between the maximum point P5 of the voltage V4 and the point P6 is 90°. Now because a duty ratio of the switching circuit 2 is 50%, the central potential is ½×V0. In addition when the switching element Q1 on the high-side is in on, V0=V1+V4 is met, and accordingly, V1=V4=½×V0 is met. Therefore as from FIG. 7, the phase difference of 90° exists between the point P6 where V1=½×V0 is met and the zero-cross point P4 of the current I1.

From the above, a value obtained by adding a phase difference of 90° to a phase at a point P7 (refer to FIG. 7) where the voltage V1 of the primary coil L1 is ½×V0 is a phase at the zero-cross point P4 of the current I1. It can be determined that the switching circuit 2 is in the phase delay mode or the phase advance mode, based on whether or not the phase at the zero-cross point P4 of the current I1 is equal to or more than 180° (refer to FIGS. 5A and 5B).

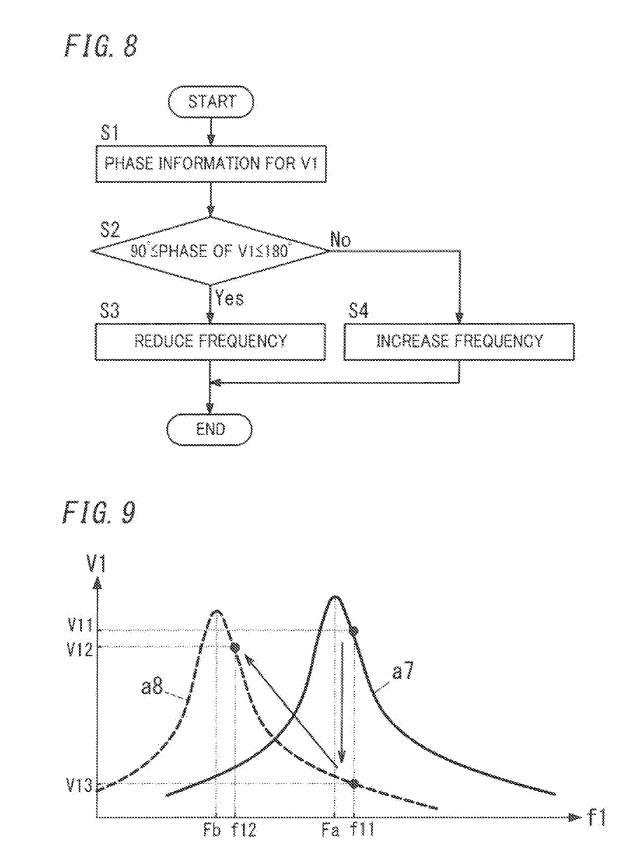

FIG. 8 shows a flow chart for explaining the operation of the CPU 32. The CPU 32 calculates the phase of the voltage V1 based on the count value (the phase information for the voltage V1) received from the capture register CR1 (Step S1). The CPU 32 then determines whether or not the phase at the point P7 of the voltage V1 (refer to FIG. 7) is equal to or more than 90° and equal to or less than 180° (Step S2). In other words, the CPU 32 determines whether or not the phase at the zero-cross point P4 of the current I1 is equal to or more than 180°.

If the phase at the point P7 of the voltage V1 is equal to or more than 90° and equal to or less than 180° (Step S2: Yes), the CPU 32 determines that the switching circuit 2 is in the phase delay mode, based on that the phase at the zero-cross point P4 of the current I1 is equal to or more than 180°. In this case, the CPU 32 reduces the drive frequency for the switching elements Q1 and Q2 so that a phase difference between the current I1 flowing through the primary coil L1 and the voltage V4 of the series circuit 1 is made closer to zero (Step S3). The drive frequency for the switching elements Q1 and Q2 is therefore made closer to the resonant frequency, which can enhance the power feeding performance.

If the phase at the point P7 of the voltage V1 is less than 90° (Step S2: No), the CPU 32 determines that the switching circuit 2 is in the phase advance mode, based on that the phase at the zero-cross point P4 of the current I1 is less than 180°. In this case, the CPU 32 increases the drive frequency for the switching elements Q1 and Q2 so as to be more than the resonant frequency, which can change the phase advance mode to the phase delay mode (Step S4). When no resonance occurs, the phase at the point P7 of the voltage V1 is 180°. For this reason, in principle, the phase at the point P7 of the voltage V1 would not exceed 180°. Although omitted in the flow chart of FIG. 8, if the phase at the point P7 of the voltage V1 is more than 180°, the CPU 32 determines that the circuit is in an abnormal state, and executes error processing.

When the power receiving device 5 is disposed at a normal position with respect to the power feeding device, a relation between a drive frequency f1 for the switching elements Q1 and Q2 of the switching circuit 2 and the voltage V1 of the primary coil L1 appears as a solid line a7 shown in FIG. 9. In this case, the drive frequency f1 for the switching elements Q1 and Q2 is at a value f11 that is near a resonant frequency Fa, and the voltage V1 of the primary coil L1 is at a value V11. The normal position mentioned here is a position where a coupling coefficient between the primary coil L1 and the secondary coil L2 is the maximum.

On the other hand, if a positional deviation occurs between the power feeding device and the power receiving device 5, the relation between the drive frequency f1 for the switching elements Q1 and Q2 of the switching circuit 2 and the voltage V1 of the primary coil L1 appears as a broken line a8 shown in FIG. 9. That is, the resonant frequency Fa is reduced to a resonant frequency Fb. Accordingly, in this case, if the drive frequency f1 for the switching elements Q1 and Q2 is maintained at the value f11, the voltage V1 of the primary coil L1 is reduced to a value V13 (V13 <V11), and therefore the power feeding performance may be also reduced.

In order to solve this issue, in the present embodiment, when the positional deviation occurs between the power feeding device and the power receiving device 5, as described above, the drive frequency fl for the switching elements Q1 and Q2 is reduced to a value f12 (f12<f11) so as to be made closer to the newly resonant frequency Fb. As a result, the voltage V1 of the primary coil L1 can be increased to a value V12 (V12>V13), which can suppress reduction in the power feeding performance.

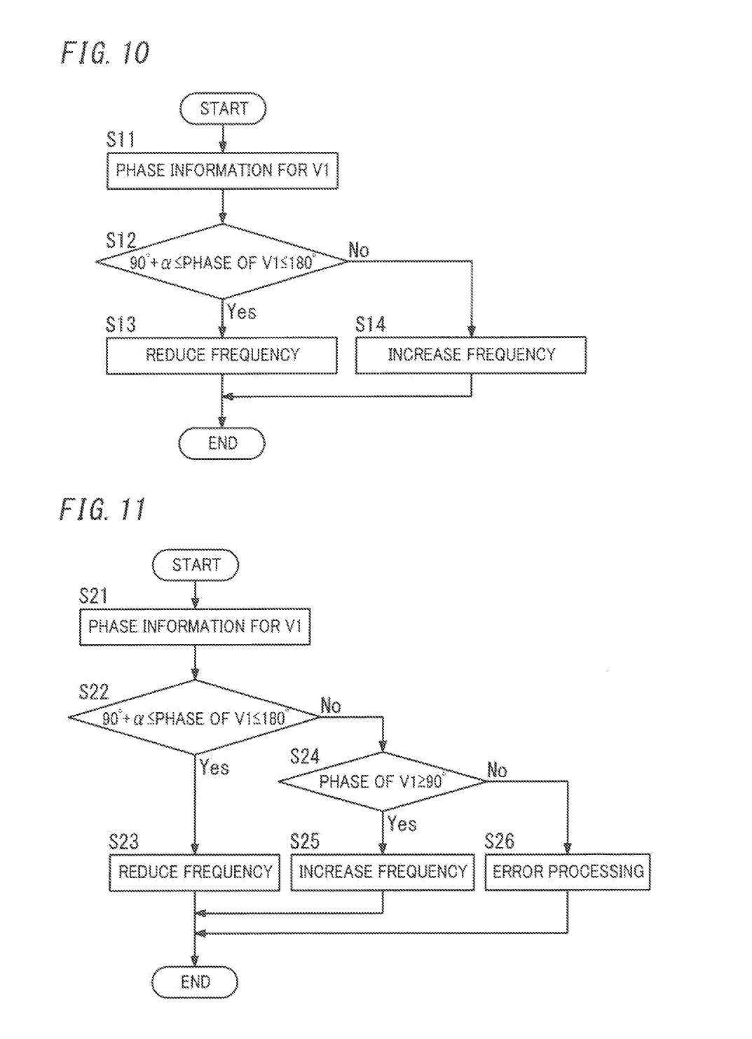

FIG. 10 is a flow chart illustrating another operation of the power feeding device of the present embodiment. In the above example, since the CPU 32 detects that the switching circuit 2 is in the phase advance mode and then deals with the issue, it means that the switching circuit 2 is temporarily operated in the phase advance mode. From this viewpoint, in order to prevent the mode from changing to the phase advance mode, it is preferable to detect the phase delay state immediately before changed to the phase advance mode. Hereinafter, this case will be described in detail with reference to FIG. 10.

The CPU 32 calculates the phase of the voltage V1 based on the count value (the phase information for the voltage Vi) received from the capture register CRI (Step S11). The CPU 32 then determines whether or not the phase at the point P7 of the voltage V1 is equal to or more than 90°+α(α>0) and equal to or less than 180° (Step S12). In other words, the CPU 32 determines whether or not the phase at the zero-cross point P4 of the current I1 is more than 180°.

If the phase at the point P7 of the voltage V1 is equal to or more than 90°+α and equal to or less than 180° (Step S12: Yes), the CPU 32 determines that the switching circuit 2 is in the phase delay mode, based on that the phase at the zero-cross point P4 of the current I1 is more than 180°. In this case, the CPU 32 reduces the drive frequency for the switching elements Q1 and Q2 so that a phase difference between the current I1 flowing through the primary coil L1 and the voltage V4 of the series circuit 1 is made closer to zero (Step S13). The drive frequency for the switching elements Q1 and Q2 is therefore made closer to the resonant frequency, which can enhance the power feeding performance.

Also even if the phase at the point P7 of the voltage V1 is less than 90°+α (Step S12: No), the CPU 32 may determine that the switching circuit 2 is in the phase delay mode, based on that the phase at the zero-cross point P4 of the current I1 is more than 180°. In this case, by increasing the drive frequency for the switching elements Q1 and Q2 (Step S14), the phase delay mode can be maintained without changing to the phase advance mode. Although omitted in the flow chart of FIG. 10, similarly to the case of FIG. 8, if the phase at the point P7 of the voltage V1 is more than 180°, the CPU 32 determines that the circuit is in an abnormal state, and executes error processing.

FIG. 11 is a flow chart illustrating yet another operation of the power feeding device of the present embodiment. In this example, error processing is additionally provided with respect to the example described above with reference to FIG. 10, and accordingly, this example is similar to the case of FIG. 10 other than the additional error processing. Hereinafter, this example will be described in detail with reference to FIG. 11.

The CPU 32 calculates the phase of the voltage V1 based on the count value (the phase information for the voltage V1) received from the capture register CRI (Step S21). The CPU 32 then determines whether or not the phase at the point P7 of the voltage V1 is equal to or more than 90°+α (α>0) and equal to or less than 180° (Step S22). In other words, the CPU 32 determines whether or not the phase at the zero-cross point P4 of the current I1 is more than 180°.

If the phase at the point P7 of the voltage V1 is equal to or more than 90°+α and equal to or less than 180° (Step S22: Yes), the CPU 32 determines that the switching circuit 2 is in the phase delay mode, based on that the phase at the zero-cross point P4 of the current I1 is more than 180°. In this case, the CPU 32 reduces the drive frequency for the switching elements Q1 and Q2 so that a phase difference between the current I1 flowing through the primary coil L1 and the voltage V4 of the series circuit 1 is made closer to zero (Step S23). The drive frequency for the switching elements Q1 and Q2 is therefore made closer to the resonant frequency, which can enhance the power feeding performance.

Also if the phase at the point P7 of the voltage V1 is less than 90°+α (Step S22: No), the CPU 32 determines whether or not the phase at the point P7 of the voltage V1 is equal to or more than 90° (Step S24). Then, If the phase at the point P7 of the voltage V1 is equal to or more than 90° (Step S24: Yes), the CPU 32 determines that the switching circuit 2 is in the phase delay mode near the resonance point, based on that the phase at the zero-cross point P4 of the current I1 is equal to or more than 180°. In this case, the CPU 32 increases the drive frequency for the switching elements Q1 and Q2 so as to avoid that the phase delay mode is changed to the phase advance mode (Step S25).

If the phase at the point P7 of the voltage V1 is less than 90° (Step S24: No), namely, if the switching circuit 2 is in the phase advance mode, the CPU 32 executes error processing (Step S26). In the error processing, for example, the alternating operation of the switching circuit 2 is preferably stopped, which can reduce malfunction of the switching circuit 2. Also for example, the alternating operation of the switching circuit 2 may be restarted by a predetermined frequency (a frequency by which the switching circuit 2 falls in the phase delay mode), after temporarily stopped. In this case, the switching circuit 2 can be operated in the phase delay mode. Although omitted in the flow chart of FIG. 11, similarly to the cases of FIGS. 8 and 10, if the phase at the point P7 of the voltage V1 is more than 180°, the CPU 32 determines that the circuit is in an abnormal state, and executes error processing.

In the present embodiment, as one example, the switching circuit 2 is a half-bridge type including the two switching elements Q1 and Q2, but the switching circuit 2 is not limited to the present embodiment and may be a full-bridge type including four switching elements, for example. The voltage input to the non-inversion input terminal of the comparator CP1 is not limited to the present embodiment, and may be a D/A output of the MCU 30.

As apparent from the embodiment described above, a power feeding device of a first aspect according to the present invention includes: a series circuit (1) including a primary coil (L1) and a capacitor (C1) connected in series with each other; a switching circuit (2); and a control circuit (3) (an MCU (30), a comparator (CP1) and diodes (D1, D2)). The power feeding device is configured to supply power from the primary coil (L1) to a secondary coil (L2) of a power receiving device (5) in a non-contact manner. The switching circuit (2) is configured to alternate a direction of a voltage between both ends of the series circuit (1). The control circuit (3) is configured to control a frequency by which the switching circuit (2) performs alternating operation for alternating the direction of the voltage. The control circuit (3) is configured to: measure a voltage (V1) at a connection point (P2) between the primary coil (L1) and the capacitor (C1); and determine, based on a phase of the voltage (V1), whether current (I1) flowing through the primary coil (L1) is in a phase advance state or a phase delay state.

According to the first aspect, since whether the current (I1) flowing through the primary coil (L1) is in the phase advance state or the phase delay state can be determined by measuring the voltage (V1) at the connection point (P2) between the primary coil (L1) and the capacitor (C1), the power feeding device does not need a detection coil for directly measuring the current, and miniaturization of the power feeding device can be therefore realized.

Regarding a power feeding device of a second aspect according to the present invention, in the first aspect, the control circuit (3) is preferably configured to increase the frequency, when determining that the current (I1) flowing through the primary coil (L1) is in the phase delay state immediately before changed from the phase delay state to the phase advance state.

According to the second aspect, since the frequency by which the switching circuit (2) performs alternating operation is increased when detecting that the current (I1) flowing through the primary coil (L1) is in the phase delay state immediately before changed from the phase delay state to the phase advance state, the phase delay state of the current (I1) can be maintained.

Regarding a power feeding device of a third aspect according to the present invention, in the first aspect or the second aspect, the control circuit (3) is preferably configured to stop the alternating operation, when determining that the current (I1) flowing through the primary coil (L1) is in the phase advance state.

According to the third aspect, it is possible to reduce malfunction of the switching circuit due to the phase advance state of the current (I1).

Regarding a power feeding device of a fourth aspect according to the present invention, in the first aspect or the second aspect, the control circuit (3) is preferably configured to temporarily stop the alternating operation and then restart the alternating operation by a predetermined frequency, when determining that the current (I1) flowing through the primary coil (L1) is in the phase advance state.

According to the fourth aspect, it is possible to reduce malfunction of the switching circuit due to operation in the phase advance state. Furthermore, since the alternating operation is restarted by the predetermined frequency higher than the resonant frequency after the stop, the operation can be performed in the phase delay state.

Regarding a power feeding device of a fifth aspect according to the present invention, in any one of the first to fourth aspects, the control circuit (3) is preferably configured to adjust the frequency, when determining that the current (I1) flowing through the primary coil (L1) is in the phase delay state. In this case, the control circuit (3) is preferably configured to adjust the frequency so that an absolute value of a phase difference between phases of: the voltage (V1) at the connection point (P2) between the primary coil (L1) and the capacitor (C1); and the current (I1) flowing through the primary coil (L1) is made closer to zero.

According to the fifth aspect, since the frequency is adjusted so that the absolute value of the phase difference between phases of the voltage (V1) and the current (I1) is made closer to zero, the power feeding performance can be enhanced.

Regarding a power feeding device of a sixth aspect according to the present invention, in any one of the first to fifth aspects, the control circuit (3) preferably includes a voltage dividing circuit (4) (resistors (R3, R4)) configured to divide the voltage (V1) at the connection point (P2) between the primary coil (L1) and the capacitor (C1).

According to the sixth aspect, even when the voltage (V1) is out of a range of the input voltage of the comparator (CP1), the voltage (V1) can be fallen within the range of the input voltage of the comparator (CP1) by the voltage dividing circuit (4).

Regarding a power feeding device of a seventh aspect according to the present invention, in any one of the first to sixth aspects, the control circuit (3) preferably includes a comparator (CP1). The comparator (CP1) has: a first terminal into which the voltage (V1) (a first voltage) at the connection point (P2) between the primary coil (L1) and the capacitor (C1) or a voltage (V2) (a second voltage) obtained by dividing the voltage (V1) is input; and a second terminal into which a prescribed reference voltage (V3) is input. The comparator is configured to output a voltage signal depending on whether the voltage (V1) or the voltage (V2) input into the first terminal is more than, less than or equal to the prescribed reference voltage (V3). The control circuit (3) preferably further includes a diode (D2) (a first voltage control circuit) configured to control the voltage (V1) or the voltage (V2) to be input into the first terminal so that the voltage (V1) or the voltage (V2) to be input into the first terminal is made equal to or higher than ground.

According to the seventh aspect, the comparator (CP1) can be operated by a single power supply.

Regarding a power feeding device of an eighth aspect according to the present invention, in any one of the first to seventh aspects, the control circuit (3) preferably includes a comparator (CP1). The comparator (CP1) has: a first terminal into which the voltage (V1) (a first voltage) at the connection point (P2) between the primary coil (L1) and the capacitor (C1) or a voltage (V2) (a second voltage) obtained by dividing the voltage (V1) is input; and a second terminal into which a prescribed reference voltage (V3) is input. The comparator (CP1) is configured to output a voltage signal depending on whether the voltage (V1) or the voltage (V2) input into the first terminal is more than, less than or equal to the prescribed reference voltage (V3). The control circuit (3) preferably further includes a diode (D1) (a second voltage control circuit) configured to control the voltage (V1) or the voltage (V2) to be input into the first terminal so that the voltage (V1) or the voltage (V2) to be input into the first terminal is made equal to or lower than the prescribed reference voltage (V3).

According to the eighth aspect, the high-voltage region to be input to the first terminal of the comparator (CP1) can be cut off, and further the potential of the reference voltage (V3) can be increased.

1. A power feeding device, comprising:
a series circuit including a primary coil and a capacitor connected in series with each other;
a switching circuit configured to alternate a direction of a voltage between both ends of the series circuit; and
a control circuit configured to control a frequency by which the switching circuit performs alternating operation for alternating the direction of the voltage,
the power feeding device being configured to supply power from the primary coil to a secondary coil of a power receiving device in a non-contact manner, and
the control circuit being configured to:
measure a voltage at a connection point between the primary coil and the capacitor; and
determine, based on a phase of the voltage, whether current flowing through the primary coil is in a phase advance state or a phase delay state,
wherein the control circuit is configured to increase the frequency, when determining that the current flowing through the primary coil is in the phase delay state immediately before changed from the phase delay state to the phase advance state.

2. (canceled)

3. The power feeding device according to claim 1, wherein the control circuit is configured to stop the alternating operation, when determining that the current flowing through the primary coil is in the phase advance state.

4. The power feeding device according to claim 1, wherein the control circuit is configured to temporarily stop the alternating operation and then restart the alternating operation by a predetermined frequency, when determining that the current flowing through the primary coil is in the phase advance state.

5. The power feeding device according to claim 1, wherein the control circuit is configured to adjust the frequency so that an absolute value of a phase difference is made closer to zero, when determining that the current flowing through the primary coil is in the phase delay state, the phase difference being a difference between phases of: an output voltage of the switching circuit; and the current flowing through the primary coil.

6. The power feeding device according to claim 1, wherein the control circuit comprises a voltage dividing circuit configured to divide the voltage at the connection point between the primary coil and the capacitor.

7. The power feeding device according to claim 1, wherein the control circuit comprises:
a comparator having
a first terminal into which a first voltage, as the voltage, at the connection point between the primary coil and the capacitor or a second voltage obtained by dividing the first voltage is input, and
a second terminal into which a prescribed reference voltage is input,
the comparator being configured to output a voltage signal depending on whether the first voltage or the second voltage input into the first terminal is more than, less than or equal to the prescribed reference voltage; and
a first voltage control circuit configured to control the first voltage or the second voltage to be input into the first terminal so that the first voltage or the second voltage to be input into the first terminal is made equal to or higher than ground.

8. The power feeding device according to claim 1, wherein the control circuit comprises:
a comparator having
a first terminal into which a first voltage, as the voltage, at the connection point between the primary coil and the capacitor or a second voltage obtained by dividing the first voltage is input, and
a second terminal into which a prescribed reference voltage is input,
the comparator being configured to output a voltage signal depending on whether the first voltage or the second voltage input into the first terminal is more than, less than or equal to the prescribed reference voltage; and
a second voltage control circuit configured to control the first voltage or the second voltage to be input into the first terminal so that the first voltage or the second voltage to be input into the first terminal is made equal to or lower than a second reference voltage that is different from the prescribed reference voltage.

9. The power feeding device according to claim 3, wherein the control circuit is configured to stop the alternating operation, when determining that the current flowing through the primary coil is in the phase advance state.

10. The power feeding device according to claim 4, wherein the control circuit is configured to stop the alternating operation, when determining that the current flowing through the primary coil is in the phase advance state.

11. The power feeding device according to claim 3, wherein the control circuit comprises a voltage dividing circuit configured to divide the voltage at the connection point between the primary coil and the capacitor.

12. The power feeding device according to claim 4, wherein the control circuit comprises a voltage dividing circuit configured to divide the voltage at the connection point between the primary coil and the capacitor.

13. The power feeding device according to claim 5, wherein the control circuit comprises a voltage dividing circuit configured to divide the voltage at the connection point between the primary coil and the capacitor.

14. The power feeding device according to claim 3, wherein the control circuit comprises:
a comparator having
a first terminal into which a first voltage, as the voltage, at the connection point between the primary coil and the capacitor or a second voltage obtained by dividing the first voltage is input, and
a second terminal into which a prescribed reference voltage is input,
the comparator being configured to output a voltage signal depending on whether the first voltage or the second voltage input into the first terminal is more than, less than or equal to the prescribed reference voltage; and
a first voltage control circuit configured to control the first voltage or the second voltage to be input into the first terminal so that the first voltage or the second voltage to be input into the first terminal is made equal to or higher than ground.

15. The power feeding device according to claim 4, wherein the control circuit comprises:
a comparator having
a first terminal into which a first voltage, as the voltage, at the connection point between the primary coil and the capacitor or a second voltage obtained by dividing the first voltage is input, and
a second terminal into which a prescribed reference voltage is input,
the comparator being configured to output a voltage signal depending on whether the first voltage or the second voltage input into the first terminal is more than, less than or equal to the prescribed reference voltage; and
a first voltage control circuit configured to control the first voltage or the second voltage to be input into the first terminal so that the first voltage or the second voltage to be input into the first terminal is made equal to or higher than ground.

16. The power feeding device according to claim 5, wherein the control circuit comprises:
a comparator having
a first terminal into which a first voltage, as the voltage, at the connection point between the primary coil and the capacitor or a second voltage obtained by dividing the first voltage is input, and
a second terminal into which a prescribed reference voltage is input,
the comparator being configured to output a voltage signal depending on whether the first voltage or the second voltage input into the first terminal is more than, less than or equal to the prescribed reference voltage; and
a first voltage control circuit configured to control the first voltage or the second voltage to be input into the first terminal so that the first voltage or the second voltage to be input into the first terminal is made equal to or higher than ground.

17. The power feeding device according to claim 6, wherein the control circuit comprises:
a comparator having
a first terminal into which a first voltage, as the voltage, at the connection point between the primary coil and the capacitor or a second voltage obtained by dividing the first voltage is input, and
a second terminal into which a prescribed reference voltage is input,
the comparator being configured to output a voltage signal depending on whether the first voltage or the second voltage input into the first terminal is more than, less than or equal to the prescribed reference voltage; and
a first voltage control circuit configured to control the first voltage or the second voltage to be input into the first terminal so that the first voltage or the second voltage to be input into the first terminal is made equal to or higher than ground.

18. The power feeding device according to claim 3, wherein the control circuit comprises:
a comparator having
a first terminal into which a first voltage, as the voltage, at the connection point between the primary coil and the capacitor or a second voltage obtained by dividing the first voltage is input, and
a second terminal into which a prescribed reference voltage is input,
the comparator being configured to output a voltage signal depending on whether the first voltage or the second voltage input into the first terminal is more than, less than or equal to the prescribed reference voltage; and
a second voltage control circuit configured to control the first voltage or the second voltage to be input into the first terminal so that the first voltage or the second voltage to be input into the first terminal is made equal to or lower than a second reference voltage that is different from the prescribed reference voltage.
